(19) United States
(12) Patent Application Publication
(10) Pub. No.: US 2018/0047763 A1
(43) Pub. Date: Feb. 15, 2018

(54) METHOD OF FABRICATING THIN FILM TRANSISTOR STRUCTURE

(71) Applicant: SHENZHEN CHINA STAR OPTOELECTRONICS TECHNOLOGY CO., LTD., Shenzhen, Guangdong (CN)

(72) Inventors: Wen SHI, Shenzhen, Guangdong (CN); Wenhui LI, Shenzhen, Guangdong (CN)

(21) Appl. No.: 15/029,253

(22) PCT Filed: Feb. 25, 2016
(86) PCT No.: PCT/CN2016/074501

§ 371 Date: Apr. 14, 2016

(30) Foreign Application Priority Data
Jan. 13, 2016 (CN) 201610022135.7

(51) Int. Cl. H01L 27/12; H01L 29/786; H01L 29/49

(52) U.S. Cl. CPC H01L 27/1288; H01L 27/1225; H01L 27/127; H01L 29/4908; H01L 29/7869

(57) ABSTRACT

A method of fabricating a thin film transistor structure is described. The method forms a photoresist pattern layer on an active pattern layer and a part of a gate insulating layer to expose a source predetermining position and a drain predetermining position of the gate insulating layer. The photoresist pattern layer has a plurality of inverted trapezoidal blocks which can be used as a mask, thereby depositing a metal layer on the photoresist pattern layer, the source predetermining position and the drain predetermining position. After removing the photoresist pattern layer and the metal layer thereon, the remaining metal layer is patterned to form a source and a drain. In the method of fabricating a thin film transistor structure, a fabricating process can be simplified, and it is unnecessary to form an etching stop layer to protect a back channel.

### FIELD OF THE INVENTION

The present invention relates to a method of fabricating a semiconductor structure, and more particularly to a method of fabricating a thin film transistor structure.

### BACKGROUND OF THE INVENTION

In a process of fabricating a conventional oxide semiconductor thin film transistor, such as an indium gallium zinc oxide thin film transistor (IGZO TFT), in order for a back channel to be protected from being etched and damaged while performing an etching process of a source and a drain, an etching stop layer (ESL) is usually formed on an oxide semiconductor layer, thereby increasing a mask procedure and increasing the complexity of the process of fabricating the thin film transistor. Moreover, in addition to the etching stop layer limiting a length of the channel, the etching stop layer is difficult to form in a display device with a relatively high resolution. Furthermore, in the process of fabricating the conventional thin film transistor, a mask procedure is required to form the source and the drain, so as to increase the complexity of the process of fabricating the thin film transistor.

As a result, it is necessary to provide a method of fabricating a thin film transistor structure to solve the problems existing in the conventional technologies.

### SUMMARY OF THE INVENTION

In view of this, the present invention provides a method of fabricating a thin film transistor structure, so as to solve the high complexity problem in the fabricating process existing in the conventional technology and the problem produced when an etching stop layer is used.

A primary object of the present invention is to provide method of fabricating a thin film transistor structure, which can simplify the fabricating process and which a source and a drain are formed without using an etching stop layer.

To achieve the above object, an embodiment of the present invention provides a method of fabricating a thin film transistor structure, comprising steps of: providing a substrate; forming a gate pattern layer on the substrate; covering a gate insulating layer on the gate pattern layer and the substrate; forming an active pattern layer on the gate insulating layer, wherein a position of the active pattern layer corresponds to that of the gate pattern layer; forming a photoresist pattern layer on the active pattern layer and a part of the gate insulating layer to expose a source predetermining position and a drain predetermining position of the gate insulating layer, wherein the photoresist pattern layer comprises a plurality of inverted trapezoidal blocks; using the photoresist pattern layer as a mask to deposit a metal layer on the photoresist pattern layer, the source predetermining position and the drain predetermining position; and removing the photoresist pattern layer to remove the metal layer on the photoresist pattern layer at the same time such that the metal layer is patterned to form a source and a drain; wherein after the step of removing the photoresist pattern layer, the method further comprises a step of: covering a passivation layer on the source, the drain, the active pattern layer, and the gate pattern layer; and wherein in the step of depositing the metal layer, the method further comprises a step of: using the photoresist pattern layer as a light mask to form a metal layer on the photoresist pattern layer, the source predetermining position, and the drain predetermining position in a sputter method.

In one embodiment of the present invention, a material of the gate pattern layer comprises aluminum, molybdenum, or copper.

In one embodiment of the present invention, the gate pattern layer is formed by a photolithography mask method.

In one embodiment of the present invention, the active pattern layer is formed by a photolithography mask method.

In one embodiment of the present invention, in the step of covering the gate insulating layer on the gate pattern layer and the substrate, the method further comprises a step of: forming the gate insulating layer by using a physical vapor deposition method.

In one embodiment of the present invention, each of the inverted trapezoidal blocks comprises a baseline surface and a topline surface, wherein the baseline surface is contacted with the active pattern layer or the gate insulating layer, and an area of the baseline surface is smaller than that of the topline surface.

In one embodiment of the present invention, each of the inverted trapezoidal blocks comprises a left-side surface and a right-side surface extended respectively from two sides of the baseline surface toward and connected with two sides of the topline surface, wherein a first angle between the left-side surface and the topline surface is greater than 0 degrees and less than 90 degrees; and a second angle between the right-side surface and the topline surface is greater than 0 degrees and less than 90 degrees.

In one embodiment of the present invention, the first angle is greater than or equal to 30 degrees and less than 90 degrees; and the second angle is greater than or equal to 30 degrees and less than 90 degrees.

To achieve the above object, another embodiment of the present invention provides a method of fabricating a thin film transistor structure, comprising steps of: providing a substrate; forming a gate pattern layer on the substrate; covering a gate insulating layer on the gate pattern layer and the substrate; forming an active pattern layer on the gate insulating layer, wherein a position of the active pattern layer is corresponding to that of the gate pattern layer, forming a photoresist pattern layer on the active pattern layer and a part of the gate insulating layer to expose a source predetermining position and a drain predetermining position of the gate insulating layer, wherein the photoresist pattern layer comprises a plurality of inverted trapezoidal blocks; using the photoresist pattern layer as a mask to deposit a metal layer on the photoresist pattern layer, the source predetermining position and the drain predetermining position; and removing the photoresist pattern layer to remove the metal layer on the photoresist pattern layer at the same time such that the metal layer is patterned to form a source and a drain.

In one embodiment of the present invention, after the step of removing the photoresist pattern layer, the method further comprises a step of: covering a passivation layer on the source, the drain, the active pattern layer, and the gate pattern layer.

In one embodiment of the present invention, in the step of depositing the metal layer, the method further comprises a step of: using the photoresist pattern layer as a light mask to form a metal layer on the photoresist pattern layer, the source predetermining position, and the drain predetermining position in a sputter method.

In one embodiment of the present invention, a material of the gate pattern layer comprises aluminum, molybdenum, or copper.

In one embodiment of the present invention, the gate pattern layer is formed by a photolithography mask method.

In one embodiment of the present invention, the active pattern layer is formed by a photolithography mask method.

In one embodiment of the present invention, in the step of covering the gate insulating layer on the gate pattern layer and the substrate, the method further comprises a step of: forming the gate insulating layer by using a physical vapor deposition method.

In one embodiment of the present invention, each of the inverted trapezoidal blocks comprises a baseline surface and a topline surface, wherein the baseline surface is contacted with the active pattern layer or the gate insulating layer, and an area of the baseline surface is smaller than that of the topline surface.

In one embodiment of the present invention, each of the inverted trapezoidal blocks comprises a left-side surface and a right-side surface extended respectively from two sides of the baseline surface toward and connected with two sides of the topline surface, wherein a first angle between the left-side surface and the topline surface is greater than 0 degrees and less than 90 degrees; and a second angle between the right-side surface and the topline surface is greater than 0 degrees and less than 90 degrees.

In one embodiment of the present invention, the first angle is greater than or equal to 30 degrees and less than 90 degrees; and the second angle is greater than or equal to 30 degrees and less than 90 degrees.

In comparison with the conventional technologies, the method of fabricating a thin film transistor structure can not only simplify the fabricating process, and it is unnecessary to form an etching stop layer used to protect a back channel.

To make the above description of the present invention more clearly comprehensible, it is described in detail below in examples of preferred embodiments with the accompanying drawings.

### DESCRIPTION OF THE DRAWINGS

FIG. 1 is a flow chart showing a method of fabricating a thin film transistor structure according to an embodiment of the present invention.

FIGS. 2A to 2G are cross-sectional schematic diagrams showing of a method of fabricating a thin film transistor structure in each of the processes according to an embodiment of the present invention.

### DETAILED DESCRIPTION OF THE PREFERRED EMBODIMENTS

The following description of the embodiments with reference to the appended drawings is used for illustrating specific embodiments which may be used for carrying out the present invention. Furthermore, the directional terms described by the present invention, such as upper, lower, top, bottom, front, back, left, right, inner, outer, side, around, center, horizontal, lateral, vertical, longitudinal, axial, radial, uppermost or lowermost, etc., are only directions by referring to the accompanying drawings. Thus, the used directional terms are used to describe and understand the present invention, but the present invention is not limited thereto.

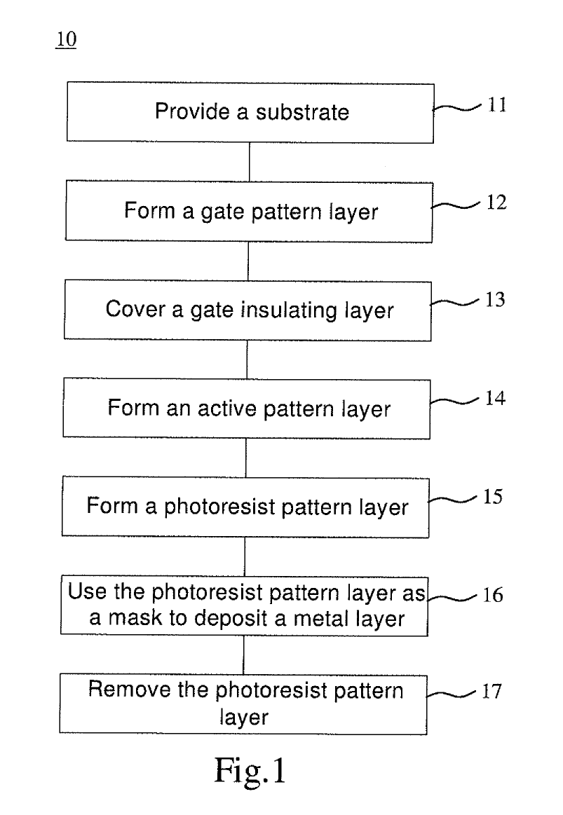

Please refer to FIG. 1A. FIG. 1A is a flow chart showing a method 10 of fabricating a thin film transistor structure according to an embodiment of the present invention. A method 10 of fabricating a thin film transistor structure of an embodiment of the present invention comprises steps of: providing a substrate (step 11); forming a gate pattern layer on the substrate (step 12); covering a gate insulating layer on the gate pattern layer and the substrate (step 13); forming an active pattern layer on the gate insulating layer, wherein a position of the active pattern layer is corresponding to that of the gate pattern layer (step 14); forming a photoresist pattern layer on the active pattern layer and a part of the gate insulating layer to expose a source predetermining position and a drain predetermining position of the gate insulating layer, wherein the photoresist pattern layer comprises a plurality of inverted trapezoidal blocks (step 15); using the photoresist pattern layer as a mask to deposit a metal layer on the photoresist pattern layer, the source predetermining position and the drain predetermining position (step 16); and removing the photoresist pattern layer to remove the metal layer on the photoresist pattern layer at the same time such that the metal layer is patterned to form a source and a drain (step 17).

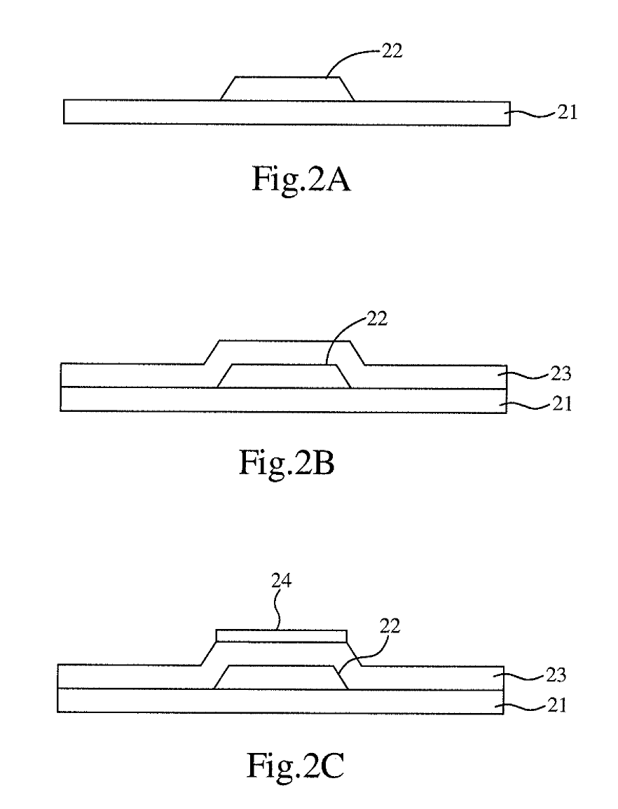

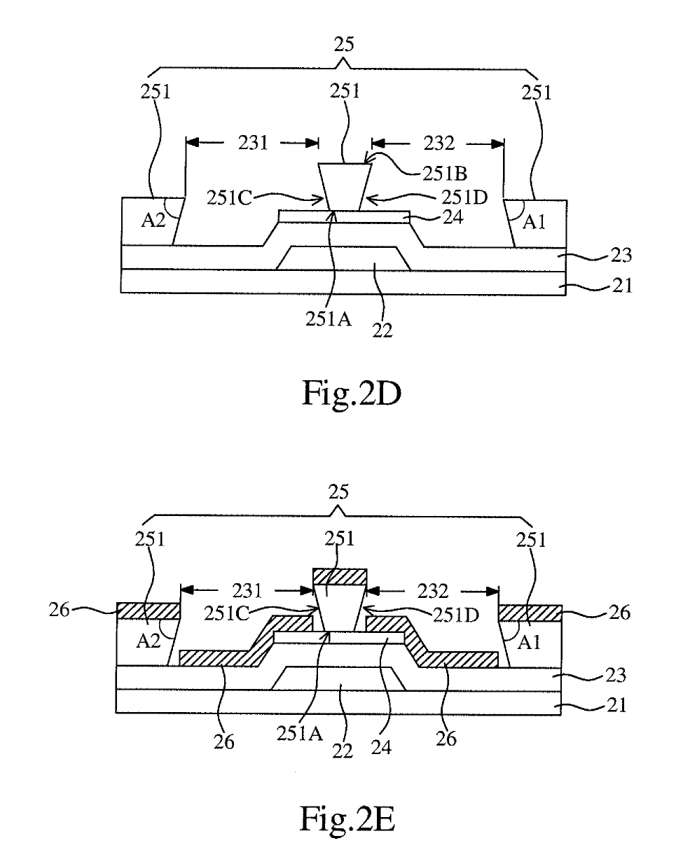

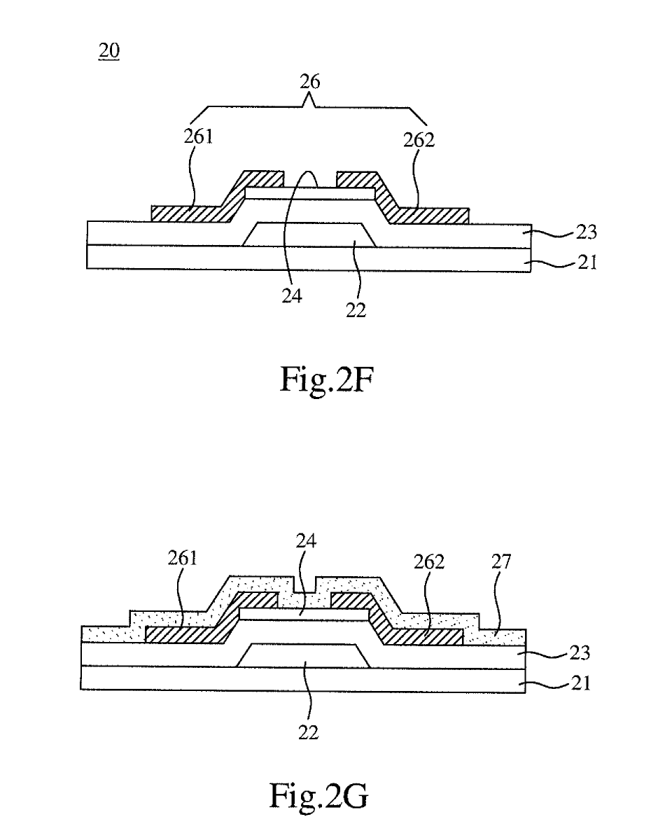

Please refer to FIGS. 1 to 2G together. FIGS. 2A to 2G are cross-sectional schematic diagrams showing a method 10 of fabricating a thin film transistor structure in each of the processes according to an embodiment of the present invention. Please refer to FIGS. 1 and 2A. In step 11, a substrate 21 is provided. In one embodiment, the substrate 21 can be a transparent substrate. In step 12, a gate pattern layer 22 is formed on the substrate 21. In one embodiment, the gate pattern layer 22 is formed by a photolithography mask method. In another embodiment, a material of the gate pattern layer 22 comprises aluminum, molybdenum, or copper.

Please refer to FIGS. 1 and 2B together. In step 13, a gate insulating layer 23 is covered with the gate pattern layer 22 and the substrate 21. In one embodiment, the gate insulating layer 23 is deposited on the gate pattern layer 22 and the substrate 21 by using a physical vapor deposition method. In step 13, the gate insulating layer 23 is formed without the requirement of using a mask.

Please refer to FIGS. 1 and 2C together. In step 14, an active pattern layer 24 is formed on the gate insulating layer, wherein a position of the active pattern layer 24 corresponds to that of the gate pattern layer 22. In one embodiment, the active pattern layer 24 is located above the gate pattern layer 22. In another embodiment, a material of the active pattern layer 24 is oxide semiconductor, such as indium gallium zinc oxide (IGZO). In a further embodiment, the active pattern layer 24 is formed by a photolithography mask method.

Please refer to FIGS. 1 and 2D together. In step 15, a photoresist pattern layer 25 is formed on the active pattern layer 24 and a part of the gate insulating layer 23 to expose a source predetermining position 231 and a drain predetermining position 232 of the gate insulating layer 23, wherein the photoresist pattern layer 25 comprises a plurality of inverted trapezoidal blocks 251. The effects of the inverted trapezoidal blocks 251 will be illustrated in step 16. In one embodiment, each of the inverted trapezoidal blocks 251 comprises a baseline surface 251A and a topline surface 251B, wherein the baseline surface 251A is contacted with the active pattern layer 24 or the gate insulating layer 23, and an area of the baseline surface 251A is smaller than that of the topline surface 251B. In another embodiment, each of the inverted trapezoidal blocks 251 comprises a left-side surface 251C and a right-side surface 251D extended respectively from two sides of the baseline surface 251A toward and connected with two sides of the topline surface 251B, wherein a first angle A1 between the left-side surface 251C and the topline surface 251B is greater than 0 degrees and less than 90 degrees; and a second angle A2 between the right-side surface 241D and the topline surface 251B is greater than 0 degrees and less than 90 degrees.

Please refer to FIGS. 1 and 2E together. In step 16, the photoresist pattern layer 25 is used as a mask to deposit a metal layer 26 on the photoresist pattern layer 25, the source predetermining position 231 and the drain predetermining position 232. It is noted that the metal layer 26 located on the source predetermining position 231 and the drain predetermining position 232 would have an obvious boundary against the metal layer 26 located on the photoresist pattern layer 25. This is due to the shape which the inverted trapezoidal blocks induce. In detail, if the photoresist pattern layer 25 is a plurality of rectangular blocks or a plurality of positive trapezoidal blocks, when the step 16 is performed, the flexibility of the metal layer itself may cause the metal layer located on the source predetermining position and the drain predetermining position to not have an obvious boundary against the metal layer located on the photoresist pattern layer, even the metal layer would maintain a layer of fluctuating structure with an entirely non-cutting section. Due to this kind of metal layer without an obvious cutting section, when the step 17 is performed, the metal layers located on the source predetermining position and the drain predetermining position are easily taken away together. From this, in addition to the photoresist pattern layer 25 including the inverted trapezoidal blocks 251 having an effect of being used as a mask, the photoresist pattern layer 25 can assist the metal layer 26 to form a pattern when the step 17 is performed.

In one embodiment, as shown in FIG. 2D, when the first angle A1 and the second angle A2 are closer to 90 degrees, the inverted trapezoidal blocks 251 can have relatively stable structures, but the effect of the cutting section is also relatively reduced; when the first angle A1 and the second angle A2 are closer to 0 degrees, the effect of the cutting section is relatively good, but the inverted trapezoidal blocks 251 have relatively non-stable structures. In order to achieve a balance between both of these, the first angle A1 can be greater than or equal to 30 degrees and less than 90 degrees, such as 45 degrees, 60 degrees, 65 degrees, 70 degrees, 75 degrees, 80 degrees or 85 degrees, and so on; and the second angle A2 can be greater than or equal to 30 degrees and less than 90 degrees, such as 45 degrees, 60 degrees, 65 degrees, 70 degrees, 75 degrees, 80 degrees or 85 degrees, and so on. It is noted that the first angle A1 can be selectively not equal to the second angle A2, for example, the first angle A1 is 30 degrees and the second angle A2 is 45 degrees.

Please refer to FIGS. 1 and 2F. In step 17, the photoresist pattern layer 25 is removed to remove the metal layer 26 on the photoresist pattern layer 25 at the same time such that the metal layer 26 is patterned to form a source 261 and a drain 262, thereby fabricating a thin film transistor structure 20 of the embodiment of the present invention.

In one embodiment, please refer to FIG. 2G. After the step 17 of removing the photoresist pattern layer 25, the method 10 of fabricating the thin film transistor of the embodiment of the present invention further comprises a step of: covering a passivation layer 27 on the source 261, the drain 262, the active pattern layer 24, and the gate pattern layer 22, thereby preventing the source 261 and the drain 262 from oxidation or corrosion.

From above, the method of fabricating the thin film transistor of the embodiment of the present invention not only reduces two mask procedures (a mask used in an etching stop layer and a mask used in etching source/drain) to simplify the fabricating process, and it is unnecessary to form an etching stop layer used to protect a back channel, so as to prevent from the problem induced from forming the etching stop layer.

The present invention has been described in relative embodiments described above. However, the above embodiments are merely examples of performing the present invention. It must be noted that the implementation of the disclosed embodiments does not limit the scope of the invention. On the contrary, modifications and equal settings included in the spirit and scope of the claims are all included in the scope of the present invention.

What is claimed is:

1. A method of fabricating a thin film transistor structure, comprising steps of:
providing a substrate;
forming a gate pattern layer on the substrate;
covering a gate insulating layer on the gate pattern layer and the substrate;
forming an active pattern layer on the gate insulating layer, wherein a position of the active pattern layer is corresponding to that of the gate pattern layer;
forming a photoresist pattern layer on the active pattern layer and a part of the gate insulating layer to expose a source predetermining position and a drain predetermining position of the gate insulating layer, wherein the photoresist pattern layer comprises a plurality of inverted trapezoidal blocks;
using the photoresist pattern layer as a mask to deposit a metal layer on the photoresist pattern layer, the source predetermining position and the drain predetermining position; and
removing the photoresist pattern layer to remove the metal layer on the photoresist pattern layer at the same time such that the metal layer is patterned to form a source and a drain;
wherein after the step of removing the photoresist pattern layer, the method further comprises a step of: covering a passivation layer on the source, the drain, the active pattern layer, and the gate pattern layer; and
wherein in the step of depositing the metal layer, the method further comprises a step of: using the photoresist pattern layer as a light mask to form a metal layer on the photoresist pattern layer, the source predetermining position and the drain predetermining position in a sputter method.

2. The method of fabricating a thin film transistor structure according to claim 1, wherein a material of the gate pattern layer comprises aluminum, molybdenum, or copper.

3. The method of fabricating a thin film transistor structure according to claim 1, wherein the gate pattern layer is formed by a photolithography mask method.

4. The method of fabricating a thin film transistor structure according to claim 1, wherein the active pattern layer is formed by a photolithography mask method.

5. The method of fabricating a thin film transistor structure according to claim 1, wherein in the step of covering the gate insulating layer on the gate pattern layer and the substrate, the method further comprises a step of: forming the gate insulating layer by using a physical vapor deposition method.

6. The method of fabricating a thin film transistor structure according to claim 1, wherein each of the inverted trapezoidal blocks comprises a baseline surface and a topline surface, wherein the baseline surface is contacted with the active pattern layer or the gate insulating layer, and an area of the baseline surface is smaller than that of the topline surface.

7. The method of fabricating a thin film transistor structure according to claim 6, wherein each of the inverted trapezoidal blocks comprises a left-side surface and a right-side surface extended respectively from two sides of the baseline surface toward and connected with two sides of the topline surface, wherein a first angle between the left-side surface and the topline surface is greater than 0 degrees and less than 90 degrees; and a second angle between the right-side surface and the topline surface is greater than 0 degrees and less than 90 degrees.

8. The method of fabricating a thin film transistor structure according to claim 7, wherein the first angle is greater than or equal to 30 degrees and less than 90 degrees; and the second angle is greater than or equal to 30 degrees and less than 90 degrees.

9. A method of fabricating a thin film transistor structure, comprising steps of:
providing a substrate;
forming a gate pattern layer on the substrate;
covering a gate insulating layer on the gate pattern layer and the substrate;
forming an active pattern layer on the gate insulating layer, wherein a position of the active pattern layer corresponds to that of the gate pattern layer;
forming a photoresist pattern layer on the active pattern layer and a part of the gate insulating layer to expose a source predetermining position and a drain predetermining position of the gate insulating layer, wherein the photoresist pattern layer comprises a plurality of inverted trapezoidal blocks;
using the photoresist pattern layer as a mask to deposit a metal layer on the photoresist pattern layer, the source predetermining position and the drain predetermining position; and
removing the photoresist pattern layer to remove the metal layer on the photoresist pattern layer at the same time such that the metal layer is patterned to form a source and a drain.

10. The method of fabricating a thin film transistor structure according to claim 9, wherein after the step of removing the photoresist pattern layer, the method further comprises a step of: covering a passivation layer on the source, the drain, the active pattern layer, and the gate pattern layer.

11. The method of fabricating a thin film transistor structure according to claim 9, wherein in the step of depositing the metal layer, the method further comprises a step of: using the photoresist pattern layer as a light mask to form a metal layer on the photoresist pattern layer, the source predetermining position, and the drain predetermining position in a sputter method.

12. The method of fabricating a thin film transistor structure according to claim 9, wherein a material of the gate pattern layer comprises aluminum, molybdenum, or copper.

13. The method of fabricating a thin film transistor structure according to claim 9, wherein the gate pattern layer is formed by a photolithography mask method.

14. The method of fabricating a thin film transistor structure according to claim 9, wherein the active pattern layer is formed by a photolithography mask method.

15. The method of fabricating a thin film transistor structure according to claim 9, wherein in the step of covering the gate insulating layer on the gate pattern layer and the substrate, the method further comprises a step of: forming the gate insulating layer by using a physical vapor deposition method.

16. The method of fabricating a thin film transistor structure according to claim 9, wherein each of the inverted trapezoidal blocks comprises a baseline surface and a topline surface, wherein the baseline surface is contacted with the active pattern layer or the gate insulating layer, and an area of the baseline surface is smaller than that of the topline surface.

17. The method of fabricating a thin film transistor structure according to claim 16, wherein each of the inverted trapezoidal blocks comprises a left-side surface and a right-side surface extended respectively from two sides of the baseline surface toward and connected with two sides of the topline surface, wherein a first angle between the left-side surface and the topline surface is greater than 0 degrees and less than 90 degrees; and a second angle between the right-side surface and the topline surface is greater than 0 degrees and less than 90 degrees.

18. The method of fabricating a thin film transistor structure according to claim 17, wherein the first angle is greater than or equal to 30 degrees and less than 90 degrees; and the second angle is greater than or equal to 30 degrees and less than 90 degrees.
